(19) United States
(12) Patent Application Publication
(10) Pub. No.: US 2010/0315116 A1
(43) Pub. Date: Dec. 16, 2010

(54) Testing method for a semiconductor integrated circuit device, semiconductor integrated circuit device and testing system

(75) Inventor: Shunichi Seya, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/801,210

(22) Filed: May 27, 2010

(30) Foreign Application Priority Data
Jun. 9, 2009 (JP) 2009-138466

(51) Int. Cl. G01R 31/26

(52) U.S. Cl. 324/762.01

(57) ABSTRACT

A method that divides semiconductor integrated circuit devices (corresponding to S1 and S2) into a plurality of groups and tests them simultaneously has the semiconductor integrated circuit devices operate with a clock signal (corresponding to CLK1 and CLK2) having a frequency different from that in other groups in at least one group. A test is performed without decreasing the number of chips tested at one time.

### TECHNICAL FIELD

### Reference to Related Application

This application is based upon and claims the benefit of the priority of Japanese patent application No. 2009-138466, filed on Jun. 9, 2009, the disclosure of which is incorporated herein in its entirety by reference thereto.

The present invention relates to a testing method for a semiconductor integrated circuit device, semiconductor integrated circuit device and testing system, and particularly to a technology that performs burn-in test on a plurality of semiconductor integrated circuit devices en bloc.

### BACKGROUND

In the testing (inspection) of a semiconductor integrated circuit device, it is preferable to simultaneously test as many chips as possible in order to reduce costs. For instance, in burn-in test using a constant temperature bath, as many chips as possible should be tested in one sequence for the sake of operational efficiency. However, due to the physical constraints of the testing system, the number of chips that can be tested in one round of burn-in testing is limited. One of the constraints is the power consumption. Even when the area of the burn-in board can accommodate a certain number of chips, it may be necessary to reduce the number of chips since the power consumption cannot exceed the capacity of the testing system.

Patent Document 1 describes a semiconductor integrated circuit device that operates so that the currents of selected semiconductor integrated circuit devices at the start of the operation are dispersed when a plurality of semiconductor integrated circuit devices are inspected at the wafer level. In this semiconductor integrated circuit device, when a plurality of semiconductor integrated circuit devices are inspected en bloc in a state where the plurality of semiconductor integrated circuit devices are formed on a semiconductor wafer, chip ID storing means outputs a corresponding chip ID upon receiving an ID select signal indicating that a semiconductor integrated circuit device is selected, and clock signal control means that receives the chip ID, the ID select signal and an external clock signal starts outputting an internal clock signal based on the value of the chip ID.

By letting each of the plurality of semiconductor integrated circuit devices have a unique ID, the output start time of the internal clock signal becomes different for each unique ID. As a result, when an external device supplies the ID select signal and a plurality of semiconductor integrated circuit devices are selected, a large current occurring in a very short period of time immediately after the selection is dispersed since a current flows in each semiconductor integrated circuit device according to internal clocks that start to operate at different times based on chip IDs different from each other. Therefore, the operation of the inspection device or each semiconductor integrated circuit device will not be unstable since the current starts to flow in each semiconductor integrated circuit device at different times.

### [Patent Document 1]

Japanese Patent No. 3811556 B2

### SUMMARY

The entire disclosure of Patent Document 1 is incorporated herein by reference thereto. The following analysis is given by the present invention.

In a semiconductor integrated circuit device, the internal operation proceeds according to the supplied clock signal when a burn-in test is performed on it. Therefore, the current consumption in the tested semiconductor integrated circuit device fluctuates over time corresponding to the proceeding internal operation.

The semiconductor integrated circuit device described in Patent Document 1 starts outputting the internal clock signal based on the value of the chip ID so that the current at the start of the test operation is dispersed. However, as the internal operation proceeds according to the clock signal, the current consumption may peak after the start of the operation and these peaks may overlap among the plurality of semiconductor integrated circuit devices. In these cases, the current consumption exceeding the capacity of the testing system may be required, and this may destabilize the operation of semiconductor integrated circuit devices.

According to an aspect of the present invention, there is provided a semiconductor integrated circuit device testing method, wherein semiconductor integrated circuit devices are divided into a plurality of groups and tested simultaneously, and the semiconductor integrated circuit devices are operated with a clock signal having a frequency different from that in other groups in at least one group.

The meritorious effects of the present invention are summarized as follows. According to the present invention, the peak value of the current consumption can be decreased and a test can be performed stably without reducing the number of chips tested at one time.

### BRIEF DESCRIPTION OF THE DRAWINGS

FIG. 1 is a block diagram showing the configuration of a testing system relating to a first example of the present invention.

FIG. 2 is a drawing showing an example of a configuration of a burn-in board.

FIG. 3 is a timing chart of signals, by way of example, in a burn-in system.

FIG. 4 is a drawing schematically showing how the power supply currents supplied from the burn-in system change.

FIG. 5 is a block diagram showing the configuration of a testing system relating to a second example of the present invention.

FIG. 6 is a block diagram showing an example of a configuration of a testing system relating to a third example of the present invention.

FIG. 7 is a drawing showing an example of a configuration of a semiconductor integrated circuit device relating to the third example of the present invention.

FIG. 8 is a timing chart of signals, by way of example, in the semiconductor integrated circuit device relating to the third example of the present invention.

FIG. 9 is a block diagram showing an example of a configuration of a testing system relating to a fourth example of the present invention.

FIG. 10 is a drawing showing an example of a configuration of a semiconductor integrated circuit device relating to the fourth example of the present invention.

FIG. 11 is a timing chart of signals, by way of example, in the semiconductor integrated circuit device relating to the fourth example of the present invention.

FIG. 12 is a block diagram showing an example of a configuration of a testing system relating to a fifth example of the present invention.

FIG. 13 is a drawing showing an example of a configuration of a semiconductor integrated circuit device relating to the fifth example of the present invention.

### PREFERRED MODES

In the following disclosure of preferred modes, the reference symbols shown within brackets relate to were exemplification for helping understanding, and not limitative to the illustrated configurations.

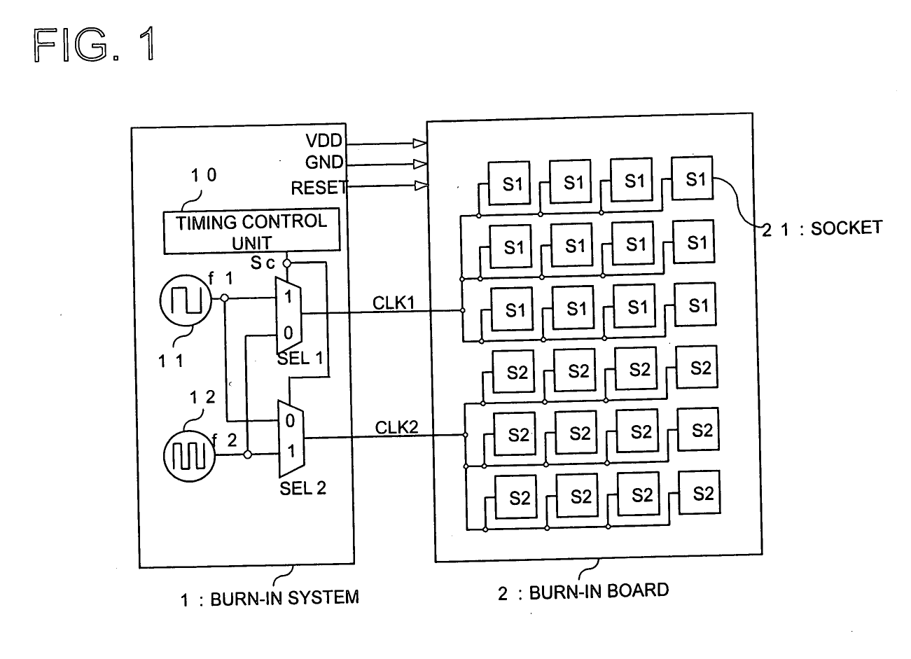

In a testing method for a semiconductor integrated circuit device relating to a mode of the present invention, semiconductor integrated circuit devices (corresponding to S1 and S2 in FIG. 1) are divided into a plurality of groups and simultaneously tested, and in at least one group, the semiconductor integrated circuit devices operate with a clock signal (corresponding to CLK1 and CLK2 in FIG. 1) having a frequency different from that in other groups.

In the testing method of the present mode, it may be configured so that a testing system (corresponding to 1 in FIG. 1) generates a clock signal corresponding to each group and supplies it to the semiconductor integrated circuit devices belonging to each group.

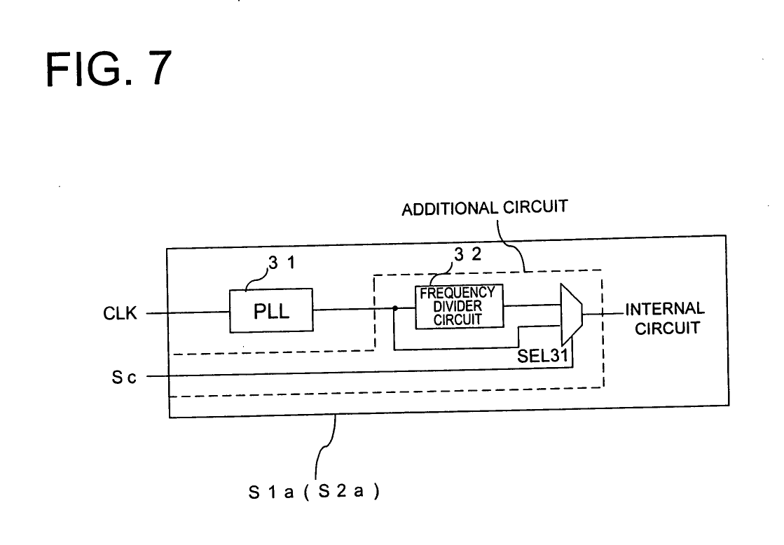

In the testing method of the present mode, it may be configured so that the semiconductor integrated circuit devices comprise a frequency division function (corresponding to 32 in FIG. 7) that divides the frequency of the supplied clock signal, and the frequency division ratio of the frequency division function in at least one group is different from the other groups.

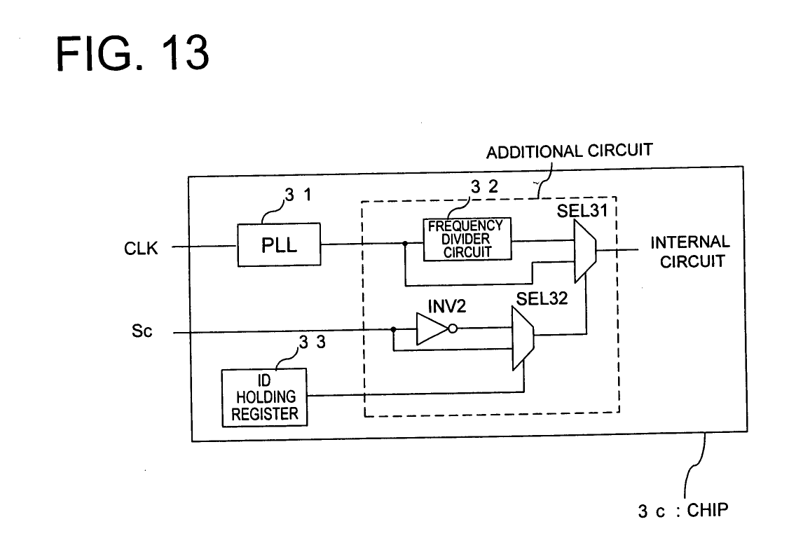

In the testing method of the present mode, it may be configured so that the semiconductor integrated circuit devices comprise a frequency division function that divides the frequency of the supplied clock signal and a chip recognition function (corresponding to 33 in FIG. 13), and in at least one group, the frequency division ratio of the frequency division function is set differently from the other groups by the chip recognition function.

In the testing method of the present mode, it may be configured so that the number of semiconductor integrated circuit devices belonging to each group is roughly the same.

In the testing method of the present mode, the number of the groups may be two.

In the testing method of the present mode, it may be configured so that the frequency of the clock signal in a group and the frequency of the clock signal in another group are alternated at a predetermined interval.

In the testing method of the present mode, the maximum power supply voltage allowed for the specification of the semiconductor integrated circuit devices may be supplied to the semiconductor integrated circuit devices.

In the testing method described above, since the semiconductor integrated circuit devices operate with the clock signals having different frequencies, the value of the power supply voltage supplied by the testing system to the semiconductor integrated circuit devices can be decreased. As a result, the test on the semiconductor integrated circuit devices can be performed stably.

Further, within the limit of the capacity of the testing system in terms of supplying the power supply voltage, the test can be performed using the maximum power supply voltage allowed for the specification of the semiconductor integrated circuit devices. In this case, since it is unnecessary to increase the capacity of the testing system or reduce the number of chips testable at one time, it is possible to avoid an increase in the costs relating to the testing.

The present invention will be described in detail using examples with reference to the drawings.

### Example 1

FIG. 1 is a block diagram showing the configuration of a testing system relating to a first example of the present invention. In FIG. 1, the testing system is constituted by a burn-in system 1 and a burn-in board 2. The burn-in system 1 comprises a timing control unit 10, clock signal generation units 11 and 12, and selectors SEL1 and SEL2. The selectors SEL1 and SEL2 select the clock signals outputted respectively by the clock signal generation units 11 and 12 in a mutually exclusive manner according to the level of a clock frequency select signal Sc outputted from the timing control unit 10, and output them as the clock signals CLK1 and CLK2 respectively to the burn-in board 2. Further, the burn-in system 1 supplies a power supply VDD, a ground GND, and a reset signal RESET to the burn-in board 2.

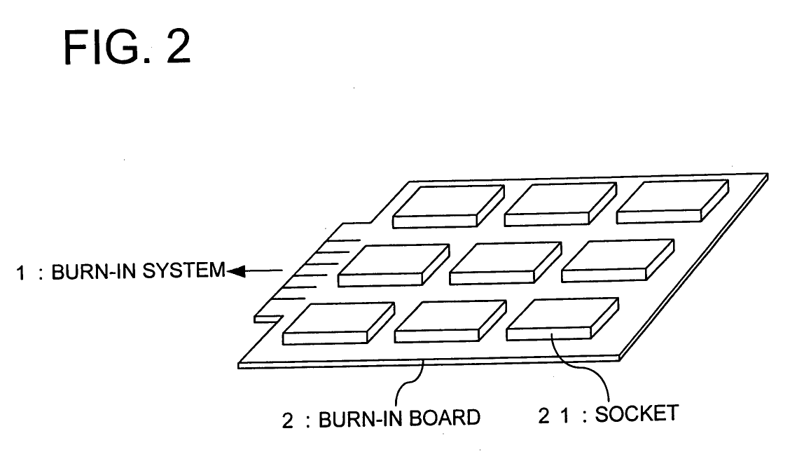

The burn-in board 2 is set up in a constant temperature bath and supplies the power supply VDD, the ground GND, and the reset signal RESET to the chips S1 and S2, which are test targets and mounted on the burn-in board 2 via sockets 21. For instance, the burn-in board 2 has a shape as shown in FIG. 2 and comprises the sockets 21 arranged in an approximate matrix form. On the burn-in board 2, the chips are divided into the chips S1 belonging to a first group and the chips S2 belonging to a second group so that the two groups have approximately the same number of chips. The clock signal CLK1 is supplied to the chips S1 and the clock signal CLK2 is supplied to the chips S2.

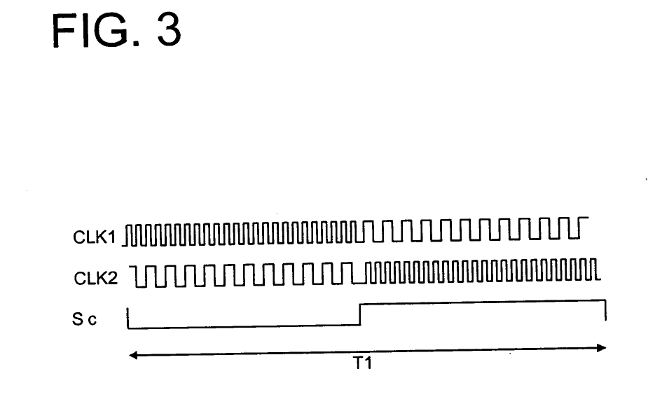

FIG. 3 is a timing chart of the signals in the burn-in system 1. In the first half of a period T1, the clock frequency select signal Sc is at a low level (0), and the selector SEL1 selects a clock signal having a frequency f2 outputted from the clock signal generation unit 12 and outputs the signal to the chips S1 as the clock signal CLK1. Further, the selector SEL2 selects a clock signal having a frequency f1 (f1<f2) outputted from the clock signal generation unit 11 and outputs the signal to the chips S2 as the clock signal CLK2.

Meanwhile, in the second half of the period T1, the clock frequency select signal Sc is at a high level (1), and the selector SEL1 selects the clock signal having the frequency f1 outputted from the clock signal generation unit 11 and outputs the signal to the chips S1 as the clock signal CLK1. Further, the selector SEL2 selects the clock signal having the frequency f2 outputted from the clock signal generation unit 12 and outputs the signal to the chips S2 as the clock signal CLK2.

After having supplied the power supply VDD, the ground GND, and the reset signal RESET, the burn-in system 1 performs a sequence of tests on the chips S1 and S2 by repeating the period T1 predetermined times. At this time, as the power supply VDD, the maximum power supply voltage allowed for the specifications of the chips S1 and S2 may be supplied. The duration of the period T1 is appropriately set according to the test content in order to avoid having the chips belonging to one group generate too much heat compared to the chips belonging to the other group due to supplying of the clock signal having the frequency f2 for a long period of time.

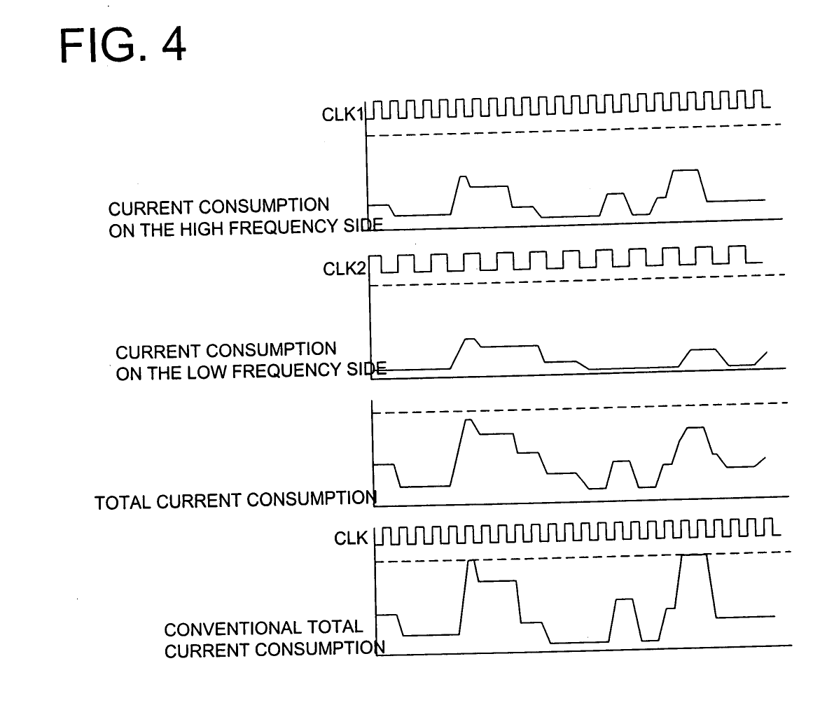

FIG. 4 is a drawing schematically showing how the power supply currents supplied from the burn-in system 1 change. The current consumption in the group to which the clock signal having the lower frequency (f1) is supplied has lower peak values and different peak times, compared to the current consumption in the group to which the clock signal having the higher frequency (f2) is supplied. As a result, the peak values of the total current consumption obtained by summing the current consumption on the high frequency side and the low frequency side are lower than the current consumption in the conventional case where the same clock signals are supplied. In other words, according to the present testing method, the peak values of the power supply currents supplied from the burn-in system 1 decrease and it is unnecessary to increase the current supply capacity of the burn-in system 1.

### Example 2

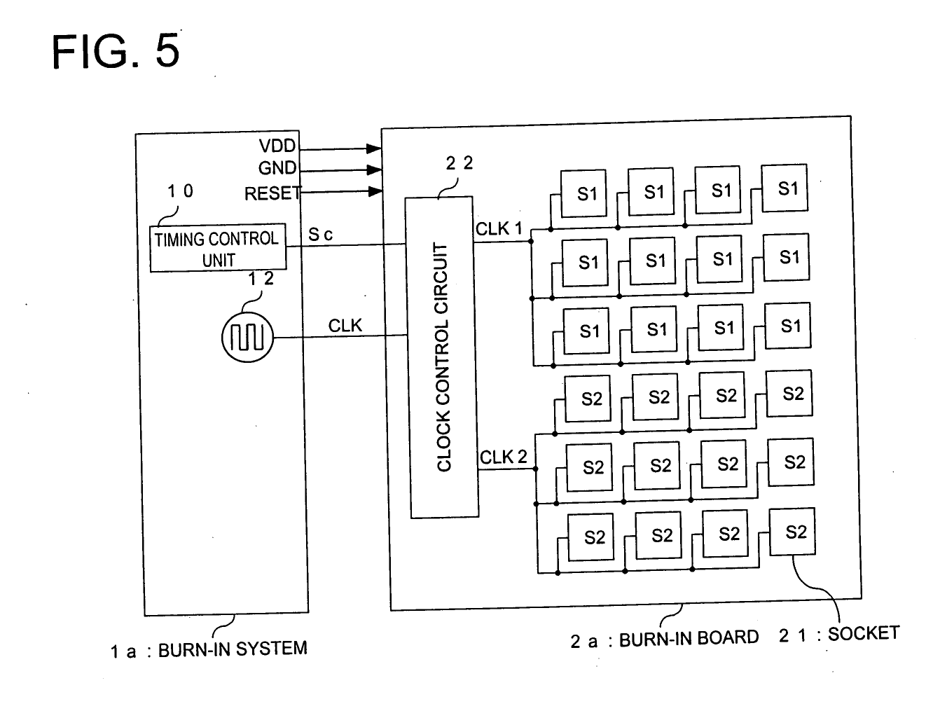

FIG. 5 is a block diagram showing the configuration of a testing system relating to a second example of the present invention. In FIG. 5, the symbols same as the ones in FIG. 1 indicate the same things, thus the explanations of them will be omitted. The testing system of the second example is constituted by a burn-in system 1a and a burn-in board 2a. The burn-in system 1a supplies the clock frequency select signal Sc from the timing control unit 10 and the clock signal CLK from the clock signal generation unit 12 to the burn-on board 2a respectively.

The burn-in board 2a comprises a clock control circuit 22. The clock control circuit 22 supplies the clock signal CLK without changing it or after frequency-dividing it to the chips S1 as the clock signal CLK1, and supplies the clock signal CLK after frequency-dividing it or without changing it to the chips S2 as the clock signal CLK2. In other words, the clock control circuit 22 comprises the function of dividing the clock signal outputted from the clock signal generation unit 12 with the clock signal outputted from the clock signal generation unit 11 and the functions of the selectors SEL1 and SEl2 in the first example. Further, the clock control circuit may be configured so that the frequency division ratio is programmable and is changed by the burn-in system la.

The testing system of the second example operates identically to that of the first example. Since there is only one transmission path relating to the clock signal between the burn-in system 1a and the burn-in board 2a in the testing system of the second example, the connection configuration is simpler than in the first example. On the other hand, since the burn-in board 2a comprises the clock control circuit 22 that repeatedly takes the stress of the burn-in tests, the burn-in board 2a is less reliable than in the first example.

### Example 3

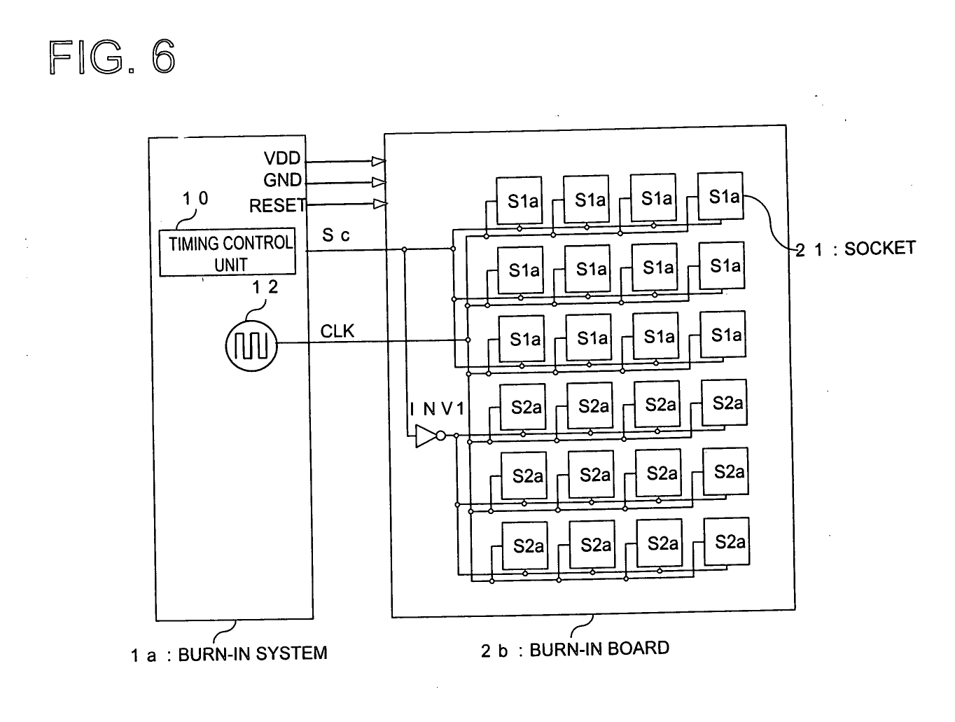

FIG. 6 is a block diagram showing the configuration of a testing system relating to a third example of the present invention. In FIG. 6, the symbols same as the ones in FIG. 5 indicate the same things, thus the explanations of them will be omitted. The testing system of the third example is constituted by the burn-in system 1a and a burn-in board 2b. The burn-in board 2b comprises an inverter circuit INV1, supplies the clock frequency select signal Sc and the clock signal CLK to chips S1a belonging to a first group, and supplies a signal obtained by having the inverter circuit INV1 invert the clock frequency select signal Sc and the clock signal CLK to chips S2a belonging to a second group.

Next, the chips S1a and S2a, which are samples burn-in tested, will be described. FIG. 7 is a drawing showing the configuration of a semiconductor integrated circuit device relating to the third example of the present invention. The chip S1a (S2a) comprises a PLL 31, a frequency divider circuit 32, and a selector SEL31. The PLL 31 receives the clock signal CLK, eliminates the jitter of the clock signal CLK, and outputs it to the frequency divider circuit 32 and to one input end of the selector SEL31. The frequency divider circuit 32 divides an output signal of the PLL 31 by for instance two, and outputs the result to the other input end of the selector SEL31. The selector SEL31 selects either the output signal of the PLL 31 or the output signal of the frequency divider circuit 32 according to the level of the clock frequency select signal Sc, and outputs it to an internal circuit not shown in the drawing as the clock signal. The chips S1a and S2a configured as described have an additional circuit portion added, compared to the semiconductor integrated circuit devices (51 and S2) relating to the first example.

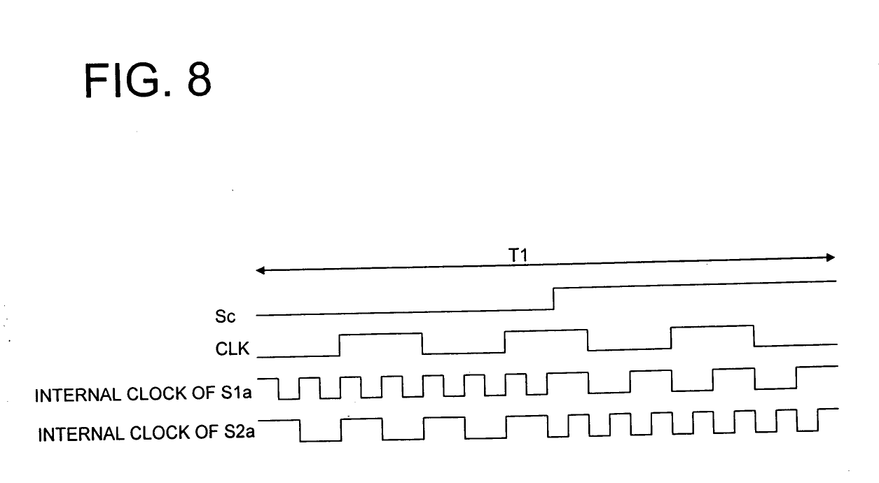

FIG. 8 is a timing chart of the signals in the semiconductor integrated circuit device relating to the third example of the present invention. In the chip S1a, for instance, when the clock frequency select signal Sc is at the low level, the output signal of the PLL 31 is outputted to the internal circuit as the internal clock, and when the clock frequency select signal Sc is at the high level, the output signal of the frequency divider circuit 32 is outputted to the internal circuit as the internal clock. On the other hand, in the chip S2a, when the clock frequency select signal Sc is at the low level, the output signal of the frequency divider circuit 32 is outputted to the internal circuit as the internal clock, and when the clock frequency select signal Sc is at the high level, the output signal of the PLL 31 is outputted to the internal circuit as the internal clock.

The testing system of the third example operates identically to that of the first example within the semiconductor integrated circuit device. Since the testing system of the third example has only one transmission path relating to the clock signal between the burn-in system 1a and the burn-in board 2b, the connection configuration can be simple as in the second example. Meanwhile, since the burn-in board 2b comprises the inverter circuit INV1, the reliability of the burn-in board 2b is higher than the second example.

### Example 4

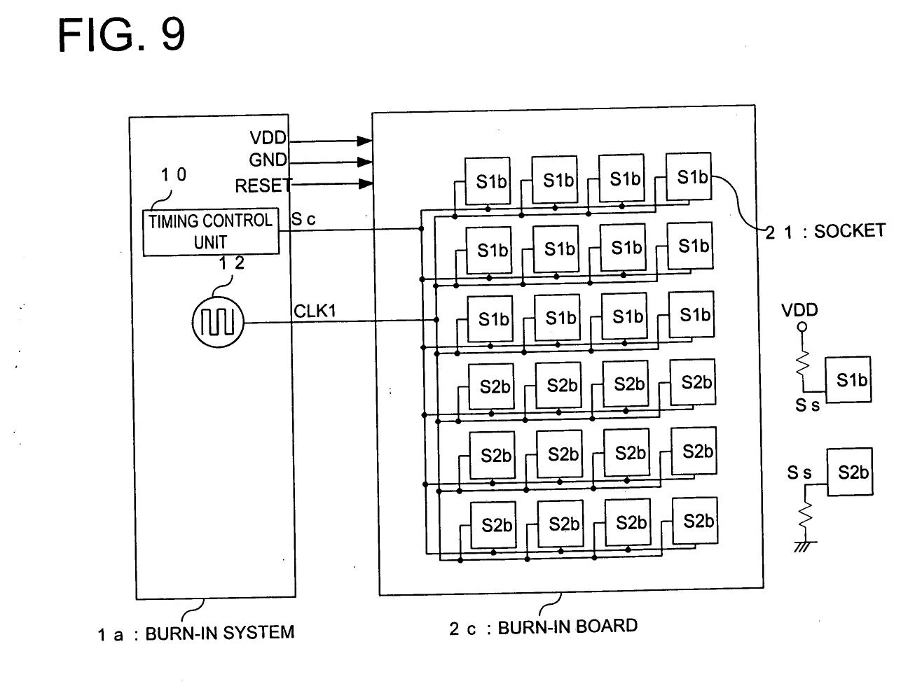

FIG. 9 is a block diagram showing the configuration of a testing system relating to a fourth example of the present invention. In FIG. 9, the symbols same as the ones in FIG. 6 indicate the same things, thus the explanations of them will be omitted. The testing system of the fourth example is constituted by the burn-in system 1a and a burn-in board 2c. The burn-in board 2c supplies the clock frequency select signal Sc and the clock signal CLK to chips S1b belonging to a first group and chips S2b belonging to a second group. In the chip S1b, a terminal Ss of the chip S1b is pulled up (connected to the power supply VDD) on the burn-in board 2c. Meanwhile, in the chip S2b, a terminal Ss of the chip S2b is pulled down (connected to the ground GND) on the burn-in board 2c.

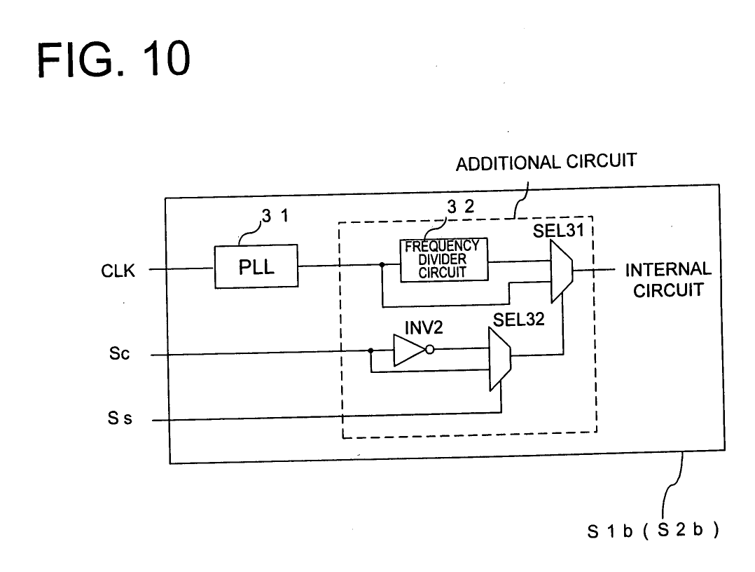

Next, the chips S1b and S2b will be described. FIG. 10 is a drawing showing the configuration of the semiconductor integrated circuit device relating to the fourth example of the present invention. In FIG. 10, the symbols same as the ones in FIG. 7 indicate the same things, thus the explanations of them will be omitted. The chip S1b (S2b) comprises an inverter circuit INV2 and a selector SEL32 as additional circuits to the chips S1a (S2a). The selector SEL32 receives the clock frequency select signal Sc at one input end and a signal obtained by having the inverter circuit INV2 invert the clock frequency select signal Sc at the other input end, selects one of the signals according to the signal level at the terminal Ss, and output it to a selection control terminal of the selector SEL31.

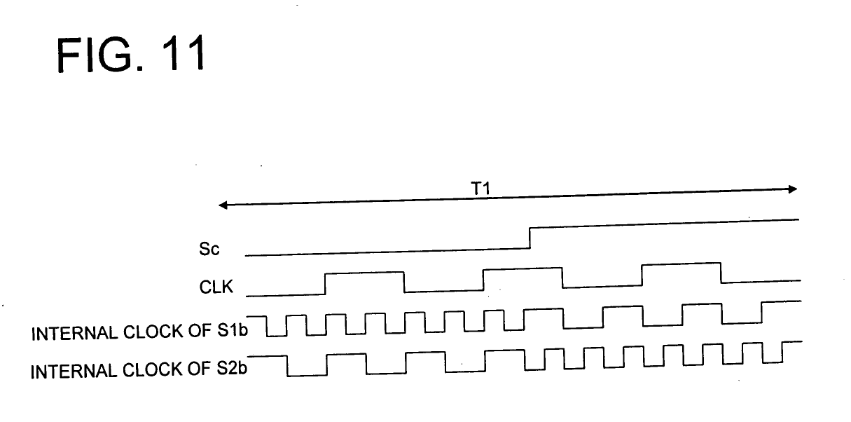

FIG. 11 is a timing chart of the signals in the semiconductor integrated circuit device relating to the fourth example of the present invention. The level at the terminal Ss is at a high level in the chip S1b, and the selector SEL32 outputs the clock frequency select signal Sc to the selection control terminal of the selector SEL31 as it is. In this case, for instance, when the clock frequency select signal Sc is at the low level, the output signal of the PLL 31 is outputted to the internal circuit as the internal clock, and when the clock frequency select signal Sc is at the high level, the output signal of the frequency divider circuit 32 is outputted to the internal circuit as the internal clock.

On the other hand, the level at the terminal Ss is at a low level in the chip S2b, and the selector SEL32 inverts the clock frequency select signal Sc and outputs the resultant signal to the selection control terminal of the selector SEL31. In this case, for instance, when the clock frequency select signal Sc is at the low level, the output signal of the frequency divider circuit 32 is outputted to the internal circuit as the internal clock, and when the clock frequency select signal Sc is at the high level, the output signal of the PLL 31 is outputted to the internal circuit as the internal clock.

The testing system of the fourth example operates identically to that of the first example within the semiconductor integrated circuit device. Since the testing system of the fourth example has only one transmission path relating to the clock signal between the burn-in system 1a and the burn-in board 2c, the connection configuration can be simple as in the second example. Further, since the burn-in board 2c comprises the pull-up circuit and the pull-down circuit (resistance element), the reliability of the burn-in board 2c is higher than the second example.

### Example 5

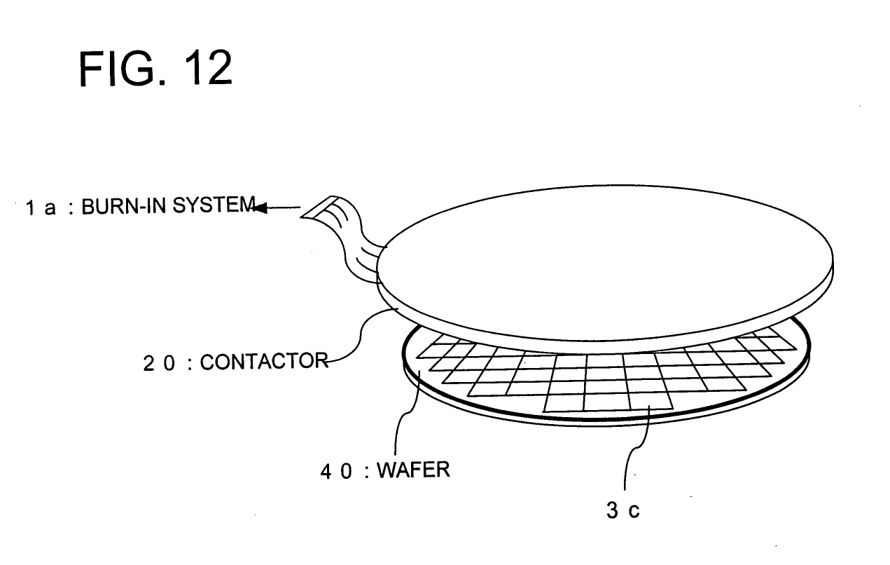

FIG. 12 is a block diagram showing the configuration of a testing system relating to a fifth example of the present invention. In FIG. 12, the testing system is constituted by the burn-in system 1a (not shown in the drawing) and a contactor (probe card) 20. The contactor 20 receives the power supply VDD, the ground GND, the reset signal RESET, the clock frequency select signal Sc, and the clock signal CLK from the burn-in system 1a, and supplies them to each of chips 3c arrayed on a wafer 40 via a contact pin.

Next, the chip 3c will be described. FIG. 13 is a drawing showing the configuration of the semiconductor integrated circuit device relating to the fifth example of the present invention. In FIG. 13, the symbols same as the ones in FIG. 10 indicate the same things, thus the explanations of them will be omitted. The chip 3c does not have the terminal Ss, unlike the chip S1b (S2b), but comprises an ID holding register 33 that holds a chip ID as an additional circuit, and an output of the ID holding register is connected to a selection control terminal of the selector SEL32. The ID holding register 33 is constituted by for instance a flash memory, and the chip ID is written into it before testing, having the ID correspond to the position on the wafer 40.

When the chip ID held by the ID holding register 33 is “1,” the chip 3c configured as described operates as in the case where the terminal Ss in FIGS. 9 and 10 is pulled up and functions identically to the chip S1b. Further, when the chip ID is “0,” the chip 3c operates as in the case where the terminal Ss is pulled down and functions identically to the chip S2b.

Example 5 can only be applied to wafer burn-in tests. The chip IDs are sequentially given to the chips 3c on the wafer 40. Therefore, it is easy to divide the chips on the wafer 40 into groups having the same number (or as close as possible to the same number) of chips using the chip IDs. However, the chips are not always arranged sequentially corresponding to the chip IDs on the burn-in board in a burn-in test after they have been cut off from the wafer and packaged. Further, chips deemed faulty in a test before the burn-in test may be removed. As a result, it is difficult to equally divide the samples on the burn-in board into groups according to the chip IDs in a burn-in test after packaging.

On the other hand, in Example 1 to 4, since the chips are divided into groups based on the disposed positions on the burn-in board without using the chip IDs, it is possible to perform the wafer burn-in test shown in FIG. 12 even after packaging.

The disclosure of the above-mentioned Patent Document is incorporated herein by reference thereto. It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A semiconductor integrated circuit device testing method, comprising:
dividing semiconductor integrated circuit devices into a plurality of groups and tests them simultaneously;
operating said semiconductor integrated circuit devices with a clock signal having a frequency different from that in other groups in at least one group.

2. The semiconductor integrated circuit device testing method as defined in claim 1, wherein a testing system generates said clock signal corresponding to each of said groups and supplies said clock signal to said semiconductor integrated circuit devices belonging to each of said groups.

3. The semiconductor integrated circuit device testing method as defined in claim 1, wherein said semiconductor integrated circuit devices comprise a frequency division function that divides the frequency of said clock signal supplied; a frequency division ratio of said frequency division function in said at least one group being different from said other groups.

4. The semiconductor integrated circuit device testing method as defined in claim 1, wherein said semiconductor integrated circuit devices comprise a frequency division function that divides the frequency of said clock signal supplied and a chip recognition function; in said at least one group, a frequency division ratio of said frequency division function being set differently from said other groups by said chip recognition function.

5. The semiconductor integrated circuit device testing method as defined claim 1, wherein the number of said semiconductor integrated circuit devices belonging to each group is about the same.

6. The semiconductor integrated circuit device testing method as defined in claim 1, wherein the number of said plurality of groups is two.

7. The semiconductor integrated circuit device testing method as defined in claim 6, wherein the frequency of said clock signal in one of said groups and the frequency of said clock signal in another of said groups are alternated at a predetermined interval.

8. The semiconductor integrated circuit device testing method as defined in claim 1, wherein a maximum power supply voltage specified for a specification of said semiconductor integrated circuit devices is supplied to said semiconductor integrated circuit devices.

9. A testing system that performs the testing method as defined in claim 1.

10. The testing system as defined in claim 9 comprising:
a burn-in system that generates said clock signal and a burn-in board that mounts said semiconductor integrated circuit devices and supplies said clock signal.

11. A semiconductor integrated circuit device produced by applying the testing method as defined in claim 1.

12. A semiconductor integrated circuit device produced by applying the testing method as defined in claim 4 and arrayed on a wafer.
